(19) United States
(12) Patent Application Publication
(10) Pub. No.: US 2016/0350935 A1
(43) Pub. Date: Dec. 1, 2016

(54) MEASURING ARRANGEMENT FOR USE WHEN DETERMINING TRAJECTORIES OF FLYING OBJECTS

(71) Applicant: Carl Zeiss SMT GmbH, Oberkochen (DE)

(72) Inventor: Matthias MANGER, Aalen-Unterkochen (DE)

(21) Appl. No.: 15/169,104

(22) Filed: May 31, 2016

Related U.S. Application Data
(63) Continuation of application No. PCT/EP2014/074576, filed on Nov. 14, 2014.

(30) Foreign Application Priority Data
Nov. 29, 2013 (DE) 10 2013 224 583.1

(51) Int. Cl. G06T 7/20; H04N 5/225; H04N 7/18; G03F 7/20; H05G 2/00

(52) U.S. Cl. CPC G06T 7/20; G03F 7/7085; G03F 7/70033; H05G 2/003; H05G 2/008; H04N 7/18; H04N 5/2252; H04N 5/2254; G06T 2207/30241

(57) ABSTRACT

A measuring arrangement for use when determining trajectories of flying objects, wherein the measuring arrangement comprises at least one photodetector arrangement (411, 412, 421, 422, 780, 785, 880, 980) comprising a plurality of photodetector cells in a monolithic construction, wherein the photodetector arrangement is assigned exactly one imaging system (700, 750, 800, 900). During the operation of the measuring arrangement, images in each case a flying object situated in an object plane (OP) of the imaging system onto the photodetector arrangement situated in an image plane (IP) of the imaging system, and a time measuring device for measuring transit instants, wherein each of the transit instants corresponds to an instant at which an image of a flying object, generated in the image plane (IP) of the imaging system, respectively crosses a cell boundary between mutually adjacent photodetector cells in the photodetector arrangement.

### CROSS REFERENCE TO RELATED APPLICATIONS

This is a Continuation of International Application PCT/EP2014/074576, which has an international filing date of Nov. 14, 2014, and the disclosure of which is incorporated in its entirety into the present Continuation by reference. The following disclosure is also based on and claims the benefit of and priority under 35 U.S.C. §119(a) to German Patent Application No. DE 10 2013 224 583.1, filed Nov. 29, 2013, which is also incorporated in its entirety into the present Continuation by reference.

### FIELD OF THE INVENTION

The invention relates to a measuring arrangement for use when determining trajectories of flying objects.

### BACKGROUND

Even though the invention is suitable in particular for measuring and predicting the flight trajectory of target droplets (e.g. tin droplets) in laser plasma sources such as, for instance, in an EUV source of a microlithographic projection exposure apparatus, the invention is not restricted thereto. In further applications, the measuring arrangement according to the present invention is also generally suitable for observing rapidly flying objects (e.g. under a microscope) or generally for observing the flight trajectory of rapidly flying projectiles.

By way of example, the use of high-speed cameras is known for observing the flight trajectory of rapidly flying projectiles. However, limits are imposed on this approach in the case of objects flying in at a high repetition rate, as is the case for instance in the application in a laser plasma source as explained below.

Laser plasma sources are used e.g. for application in lithography. In this regard, for instance, during the operation of a projection exposure apparatus designed for the EUV range (e.g. at wavelengths of e.g. approximately 13 nm or approximately 7 nm), the required EUV light is generated by an EUV light source based on a plasma excitation, with respect to which FIG. 10 shows an exemplary conventional construction. This EUV light source firstly comprises a CO₂ laser (not shown) for generating infrared radiation 306 having a wavelength of λ≈10.6 μm, which is focussed by a focussing optical unit, passes through an opening 311 present in a collector mirror 310 embodied as an ellipsoid and is directed onto a target material 332 (e.g. tin droplet) that is generated by a target source 335 and is fed to a plasma ignition position 330. The infrared radiation 306 heats the target material 332 situated in the plasma ignition position 330 in such a way that this target material undergoes transition to a plasma state and emits EUV radiation. This EUV radiation is focussed onto an intermediate focus IF by the collector mirror 310 and passes through this intermediate focus into a downstream illumination device, the boundary 340 of which is merely indicated and which has a free opening 341 for the entrance of light.

What is of major importance for the dose stability and power that can be obtained in an EUV light source in this case is that the tin droplets “flying in” very rapidly (e.g. with an injection rate in the region of 100 kHz or with a temporal spacing of e.g. 10 μs) into the laser plasma source as the light demand increases are struck individually highly accurately (with an accuracy of e.g. below 1 μm) and reproducibly by the laser beam that atomizes the droplet. One problem that occurs here is that the conversion of a droplet to a plasma is accompanied in each case by a reaction on the rest of the droplets or a deflection of the rest of the droplets which are already situated in the feed path, which makes it more difficult to carry out an exact prediction of the flight trajectory and, if appropriate, to implement suitable measures for influencing it.

### SUMMARY

It is an object of the present invention to provide a measuring arrangement for use when determining trajectories of flying objects which enables the flight trajectory to be determined and predicted as accurately and promptly as possible even in the case of objects flying in at high frequency, such as e.g. target droplets in a laser plasma source for EUV lithography.

A measuring arrangement according to the invention for use when determining trajectories of flying objects comprises:
at least one photodetector arrangement comprising a plurality of photodetector cells in a monolithic construction;
wherein the photodetector arrangement is assigned exactly one imaging system, which, during the operation of the measuring arrangement, images in each case a flying object situated in an object plane of the imaging system onto the photodetector arrangement situated in an image plane of the imaging system; and
a time measuring device for measuring transit instants, wherein each of the transit instants corresponds to an instant at which an image of a flying object, the image being generated in the image plane of the imaging system, in each case crosses a cell boundary between mutually adjacent photodetector cells in the photodetector arrangement.

In this case, although the basic principle of determining trajectories on the basis of the measurement of transit instants itself forms the starting point for the concepts underlying the present invention, it does not per se belong to the claimed subject matter of the present application. Rather, the invention utilizes the concept of providing an optoelectronic realization for measuring flight trajectories or determining trajectories by a flying object being imaged with an imaging system (in the object plane of which the object is situated) onto a suitably configured photodetector arrangement embodied in a monolithic fashion, wherein imaginary target lines are defined or embodied optoelectronically by the cell boundaries between mutually adjacent photodetector cells and wherein the crossing of these target lines (i.e. the transit instants at which the crossing takes place in each case) is measurable using suitable electronic switching elements.

In this case, the invention is distinguished, in particular, by the fact that owing to the circumstance that only transmit times with regard to the crossing of target lines suitably defined previously (that is to say start and stop times) have to be evaluated for the purpose of measuring flight trajectories, the required items of information are present in each case directly with respect to time, without for instance firstly the need to carry out or await a comparatively time-consuming image evaluation as in the case when high-speed cameras are used. As a result, it is thus possible to achieve an accurate and prompt determination and prediction of the flight trajectory at very high repetition rates (e.g. in the range of from 10 kHz to more than 100 kHz) and with a very low “data age” (e.g. far less than 10 μs).

Even though the invention is suitable in particular for measuring and predicting flight trajectories of target droplets (e.g. tin droplets) in laser plasma sources, such as, for instance, in an EUV source of a microlithographic projection exposure apparatus, the invention is not restricted thereto. In further applications, the sensor arrangement according to the present invention is also generally suitable for observing rapidly flying objects e.g. under a microscope or generally for observing the flight trajectory of rapidly flying projectiles.

In accordance with one embodiment, the imaging system is configured as a replicating imaging system which generates at least two images of the object in the image plane. This makes possible, as described in even more detail below, the use of a photodetector arrangement which is constructed in a “folded” manner (in which the individual photodetector cells are arranged non-linearly) and which allows a shortening of the required measurement section or a reduction of the image field extent in the imaging system according to the invention in comparison with an “unfolded” photodetector arrangement (having a linear arrangement of the individual photodetector cells), that is to say overall a “relaxation” of the requirements made of the imaging system.

Depending on the existing size ratios or accuracy requirements, the imaging system can be configured in a magnifying or else reducing fashion.

In accordance with one embodiment, the imaging system has at least one diffractive structure, which is preferably arranged in a pupil plane of the imaging system. During the operation of the measuring arrangement with monochromatic light, this enables a replication of the imaging beam path for the use of a photodetector arrangement constructed in a “folded” manner.

In accordance with one embodiment, the imaging system has at least one optical beam splitter. During the operation of the measuring arrangement with polychromatic light, too, this enables a replication of the imaging beam path for the use of a photodetector arrangement constructed in a “folded” manner.

In accordance with one embodiment, the imaging system has at least one intermediate image. The corresponding intermediate image plane can be used to suppress undesired parasitic light and disturbing reflections with the aid of a stop.

In accordance with one embodiment, the photodetector cells are configured as photodiodes. However, the invention is not restricted thereto, and so other photodetectors, such as e.g. photoresistors, can also be used in further embodiments.

In accordance with one embodiment, the photodetector arrangement is configured in such a way that at least one cell boundary between mutually adjacent photodetector cells runs at an angle of 45°±5° with respect to a centroid trajectory of the flying object. Furthermore, the photodetector arrangement can be configured in such a way that a first cell boundary between mutually adjacent photodetector cells and at least a second cell boundary between mutually adjacent photodetector cells run parallel to one another. Such configuration of the cell boundaries in the photodetector arrangement used according to the invention makes it possible, as explained in even greater detail below, to obtain as it were an optimization of the mathematical definiteness or determinability of the set of parameters describing the flight trajectory or trajectory.

In further embodiments of the invention, the (transit time) information of cell boundaries or target lines which are actually redundant (i.e. which are not necessarily required or are “surplus” per se for determining the set of parameters describing the trajectory) can also be used to obtain an increased accuracy of the measurement.

In accordance with one embodiment, the measuring arrangement is integrated into a control loop for controlling the trajectories of flying objects, for controlling a radiation field acting on the objects and/or for controlling an entity acting on the objects (e.g. a material-processing laser beam). The information obtained about the flight trajectory can thus be used, for example, to have a correcting influence on the object itself (e.g. in a laser plasma source the target droplets or tin droplets to be struck) or an entity acting on the objects.

In accordance with one embodiment, the measuring arrangement furthermore comprises at least one camera in the imaging beam path of the imaging system. Such a camera, which can be equipped e.g. with a pixelated 2D image sensor, can serve in particular for supporting the alignment or for diagnosis purposes.

In accordance with one embodiment, the measuring arrangement comprises at least two imaging systems, wherein a photodetector arrangement comprising in each case a plurality of photodetector cells in a monolithic construction is in each case arranged in the image plane of each of these imaging systems. In this way, the trajectory to be measured of the flying object can be observed at mutually different angles, with the consequence that the complete three-dimensional trajectory can also be ascertained from the two-dimensional trajectories (or projections) respectively obtained.

In accordance with one embodiment, the measuring arrangement is configured for use when determining trajectories of target droplets of a laser plasma source, in particular of an EUV source of a microlithographic projection exposure apparatus.

Further configurations of the invention can be gathered from the description and the dependent claims.

The invention is explained in greater detail below on the basis of exemplary embodiments illustrated in the accompanying figures.

### BRIEF DESCRIPTION OF THE DRAWINGS

In the figures:

FIG. 1 shows a schematic illustration for elucidating the principle forming a starting point for the present invention;

FIGS. 2A-D show schematic illustrations for elucidating an optoelectronic embodiment of a target line that is realized in the context of the present invention;

FIG. 3 shows a schematic illustration for elucidating a time-of-flight measurement effected in the context of the present invention in accordance with one possible embodiment;

FIGS. 4A-B show schematic illustrations for elucidating possible embodiments of a photodetector arrangement comprising respective pluralities of photodetector cells;

FIG. 5 shows a schematic illustration depicting further possible embodiments of a photodetector arrangement using possible folding schemes with regard to the arrangement of photodetector cells;

FIGS. 6A-D show schematic illustrations for elucidating different target line configurations and the assessment thereof;

FIGS. 7A-B show schematic illustrations in each case of a possible imaging beam path realized within a measuring arrangement according to the invention;

FIGS. 8-9 show schematic illustrations in each case of a possible construction of an imaging system and the arrangement thereof within a measuring arrangement according to the invention; and

FIG. 10 shows a schematic illustration of the construction of an EUV light source in accordance with the prior art.

### DETAILED DESCRIPTION

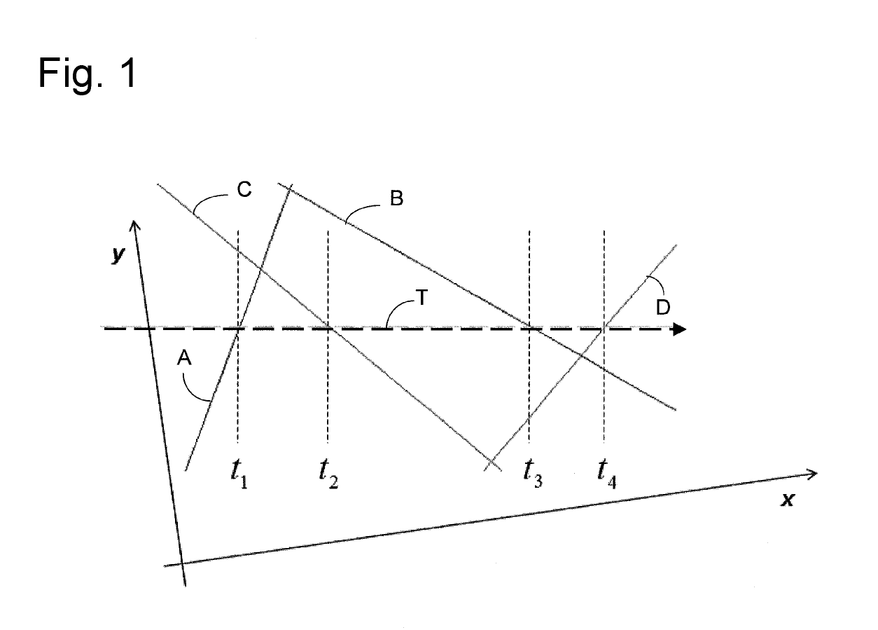

The realization according to the invention of a measuring arrangement for use when determining trajectories of flying objects is based on the principle that a trajectory determination, i.e. the determination of the flight trajectory parameters of a flying object, can be carried out on the basis of the measurement of transit instants concerning the crossing of defined target lines. In this case, each of the transit instants is assigned to a target line from a plurality of target lines and corresponds to that instant at which a flying object in each case crosses the target line. FIG. 1 serves to illustrate this principle, wherein the object's flight trajectory that is to be detected metrologically is designated by “T” and wherein merely by way of example four target lines “A”-“D” are depicted in FIG. 1, wherein the transit instants at which the respective target line is crossed by the object are designated by “t₁”-“t₄”. With knowledge of the geometry of the target lines, the flight trajectory parameters can then be calculated on the basis of the measured transit times “t₁”-“t₄”, as described below.

The mathematical foundations underlying this principle will firstly be explained below. A linear three-dimensional flight trajectory of a flying object or projectile can basically be described by the equation

$$( \begin{matrix}X ( t ) \\ Y ( t ) \\ Z ( t )\end{matrix} ) = ( \begin{matrix}{X}_{0} \\ {Y}_{0} \\ {Z}_{0}\end{matrix} ) + ( t - {t}_{0} ) ( \begin{matrix}U \\ V \\ W\end{matrix} ) \qquad ( 1 )$$

wherein X(t), Y(t), Z(t) denote the position coordinates at the time t, X₀, Y₀, Z₀ denote the position coordinates at the time t₀ and U, V, W denote the velocity components. If—as described in even greater detail below in association with the embodiments of the invention—an imaging system is then used to image the flying object situated in an object plane of the imaging system into an image plane, this imaging onto the image plane given the image distance B can be described using the intercept theorem by:

$$( \begin{matrix}x ( t ) \\ y ( t )\end{matrix} ) = \frac{- B}{Z ( t )} ( \begin{matrix}X ( t ) \\ Y ( t )\end{matrix} ) = \frac{- B}{{Z}_{0} + ( t - {t}_{0} ) W} ( \begin{matrix}{X}_{0} + ( t - {t}_{0} ) U \\ {Y}_{0} + ( t - {t}_{0} ) V\end{matrix} ) \qquad ( 2 )$$

If an orientation of the flight trajectory that is perpendicular to the optical axis (z-axis) is taken as a basis, then W=0 holds true for the velocity component W in the z-direction, and equation (2) is simplified as

$$( \begin{matrix}x ( t ) \\ y ( t )\end{matrix} ) = \frac{- B}{{Z}_{0}} ( \begin{matrix}{X}_{0} + ( t - {t}_{0} ) U \\ {Y}_{0} + ( t - {t}_{0} ) V\end{matrix} ) = ( \begin{matrix}{x}_{0} + ( t - {t}_{0} ) u \\ {y}_{0} + ( t - {t}_{0} ) v\end{matrix} ) \qquad ( 3 )$$

with the abbreviations

$$( \begin{matrix}{x}_{0} \\ {y}_{0}\end{matrix} ) = M ( \begin{matrix}{X}_{0} \\ {Y}_{0}\end{matrix} ) and ( \begin{matrix}u \\ v\end{matrix} ) = M ( \begin{matrix}U \\ V\end{matrix} )$$

and the imaging scale

$$M = \frac{- B}{{Z}_{0}} .$$

The flight trajectory of the object is then determined according to the invention by way of a metrological determination of the set of parameters of the projected flight trajectory which includes the two location point position coordinates x₀ and y₀ and the two velocity components u and v. In order to determine these four unknown flight trajectory parameters, it is necessary to define at least four of such target lines in a suitable configuration. For the mathematical description, firstly a dedicated reference coordinate system is introduced for each target line k=1, . . . , K, the system arising as a result of the rotation of the original coordinate axes by a rotation angle θₖ. The flight trajectory description in the respective coordinate system then reads

$$( \begin{matrix}{x}_{k} ( t ) \\ {y}_{k} ( t )\end{matrix} ) = ( \begin{matrix}{cs}_{k} & - {sn}_{k} \\ {sn}_{k} & {cs}_{k}\end{matrix} ) ( \begin{matrix}{x}_{0} + ( t - {t}_{0} ) u \\ {y}_{0} + ( t - {t}_{0} ) v\end{matrix} ) \qquad ( 4 )$$

with the abbreviations csₖ=cos(θₖ) and snₖ=sin(θₖ). The corresponding transformation for the coordinate axes is given by

$$( \begin{matrix}{\hat{x}}_{k} \\ {\hat{y}}_{k}\end{matrix} ) = ( \begin{matrix}{cs}_{k} & {sn}_{k} \\ - {sn}_{k} & {cs}_{k}\end{matrix} ) ( \begin{matrix}\hat{x} \\ \hat{y}\end{matrix} ) . \qquad ( 5 )$$

Hereinafter, without any restriction of the generality, a target line is defined as a straight line which is parallel to the rotated) yₖ-axis and which intersects the rotated xₖ-axis at the position xₖ. For the crossing of the target line (i.e. the “target line transit”) there follows from equation (4) after suitable transformation the relationship

$${x}_{k} = ( \begin{matrix}{cs}_{k} & - {sn}_{k} & {cs}_{k} ( {t}_{k} - {t}_{0} ) & - {sn}_{k} ( {t}_{k} - {t}_{0} )\end{matrix} ) ( \begin{matrix}{x}_{0} \\ {y}_{0} \\ u \\ v\end{matrix} ) \qquad ( 6 )$$

Stacking at least four of such equations results in the following conditional equation for the flight trajectory parameters

$$( \begin{matrix}{x}_{1} \\ {x}_{2} \\ ⋮ \\ {x}_{K}\end{matrix} ) = {\underbrace{( \begin{matrix}{cs}_{1} & - {sn}_{1} & {cs}_{1} ( {t}_{1} - {t}_{0} ) & - {sn}_{1} ( {t}_{1} - {t}_{0} ) \\ {cs}_{2} & - {sn}_{2} & {cs}_{2} ( {t}_{2} - {t}_{0} ) & - {sn}_{2} ( {t}_{2} - {t}_{0} ) \\ ⋮ & & & \\ {cs}_{K} & - {sn}_{K} & {cs}_{K} ( {t}_{K} - {t}_{0} ) & - {sn}_{K} ( {t}_{K} - {t}_{0} )\end{matrix} )}}_{{M}_{\underline{\_}}} ( \begin{matrix}{x}_{0} \\ {y}_{0} \\ u \\ v\end{matrix} ) \qquad ( 7 )$$

With knowledge of the geometry and the transit times, the flight trajectory parameters sought are finally obtained therefrom, by inverting the design matrix M, as

$$( \begin{matrix}{x}_{0} \\ {y}_{0} \\ u \\ v\end{matrix} ) = inv ( {{M}_{\underline{\_}}}^{T} {M}_{\underline{\_}} ) {{M}_{\underline{\_}}}^{T} ( \begin{matrix}{x}_{1} \\ {x}_{2} \\ ⋮ \\ {x}_{K}\end{matrix} ) \qquad ( 8 )$$

Proceeding from the above mathematical considerations and equations obtained, an optoelectronic realization of the flight trajectory measurement or trajectory determination is then carried out according to the invention by virtue of the fact that the respective object to be measured in terms of its flight trajectory is imaged onto a suitably configured photodetector arrangement with an imaging system (in the object plane of which the object is situated). In this case, precisely the target lines described above are defined or optoelectronically embodied by the cell boundaries between mutually adjacent photodetector cells, and the crossing of the target lines (i.e. the transit times) becomes directly measurable using suitable electronic switching elements.

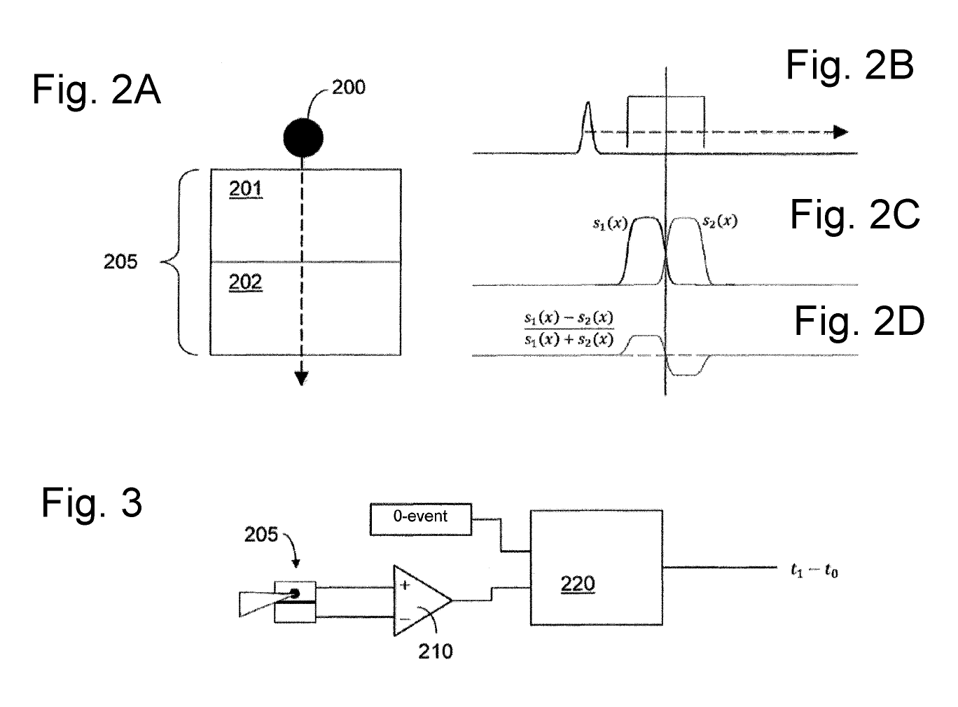

The optoelectronic realization or embodiment of the target lines described above is firstly explained below with reference to FIG. 2-4.

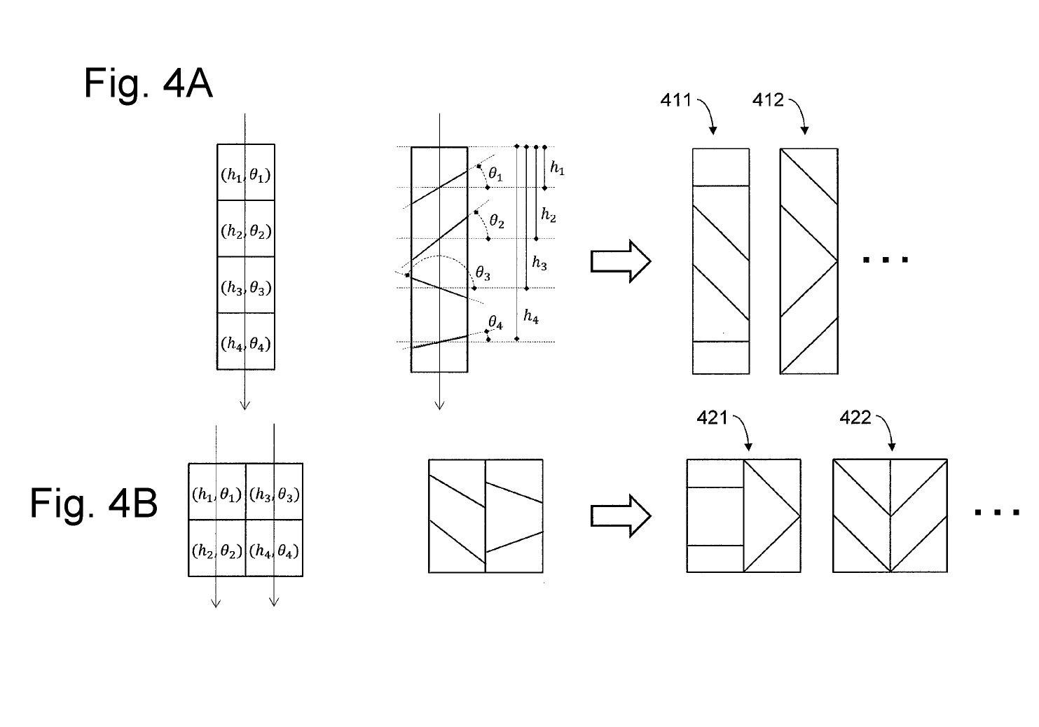

FIG. 2A schematically indicates how a light spot 200 proceeding from a flying object successively passes through a first optoelectronic sensor in the form of a first photodiode 201 and a second optoelectronic sensor in the form of a second photodiode 202. FIG. 2B indicates an energy distribution which corresponds to the light spot 200 and is modelled as Gaussian, and the respective sensor signals s₁(x) and s₂(x) of the photodiodes 201, 202 are plotted in FIG. 2C. For the difference signal ((s₁(x)−s₂(x))/s₁(x)+s₂(x)) normalized to the total intensity and plotted in FIG. 2D, a zero crossing arises at the transition between the two photodiodes 201, 202. A target line can then be defined by the transition, wherein a circuitry realization for generating a trigger signal upon the target line being crossed is illustrated schematically in FIG. 3. As a “transit detector” for the crossing of the target line, use is made here of a Schmitt trigger 210, which, for a connected TDC component 220, generates a start/stop trigger signal that is sufficiently precise in so far as resolutions of the (flight) time measurement in the range of 100 ps can be realized here.

Proceeding from the optoelectronic realization of an individual target line as described above with reference to FIGS. 2 and 3, the realization of a desired target line configuration (containing a number k of target lines) is then effected according to the invention by the provision of a monolithically embodied photodetector arrangement having a plurality of photodetector cells in a geometry coordinated with the target line configuration. An imaging system is used in conjunction with the photodetector arrangement, as explained in even greater detail below, and the photodetector arrangement is arranged in an image plane of the imaging system, such that the flying object situated in an object plane of the imaging system is imaged onto the photodetector arrangement situated in the image plane.

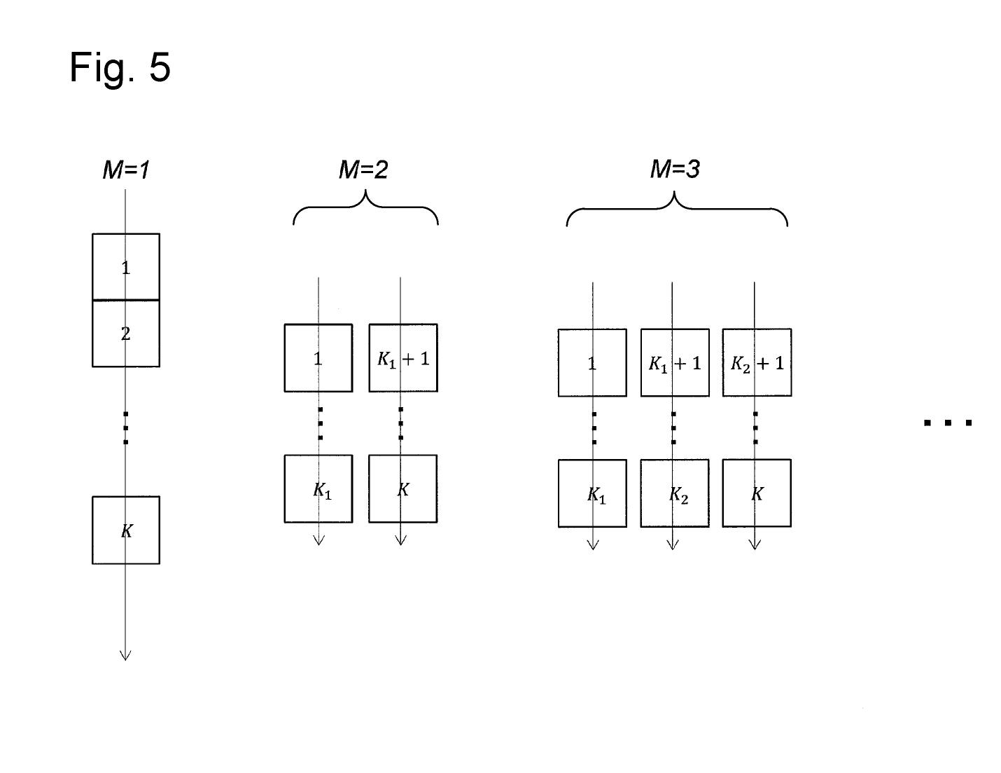

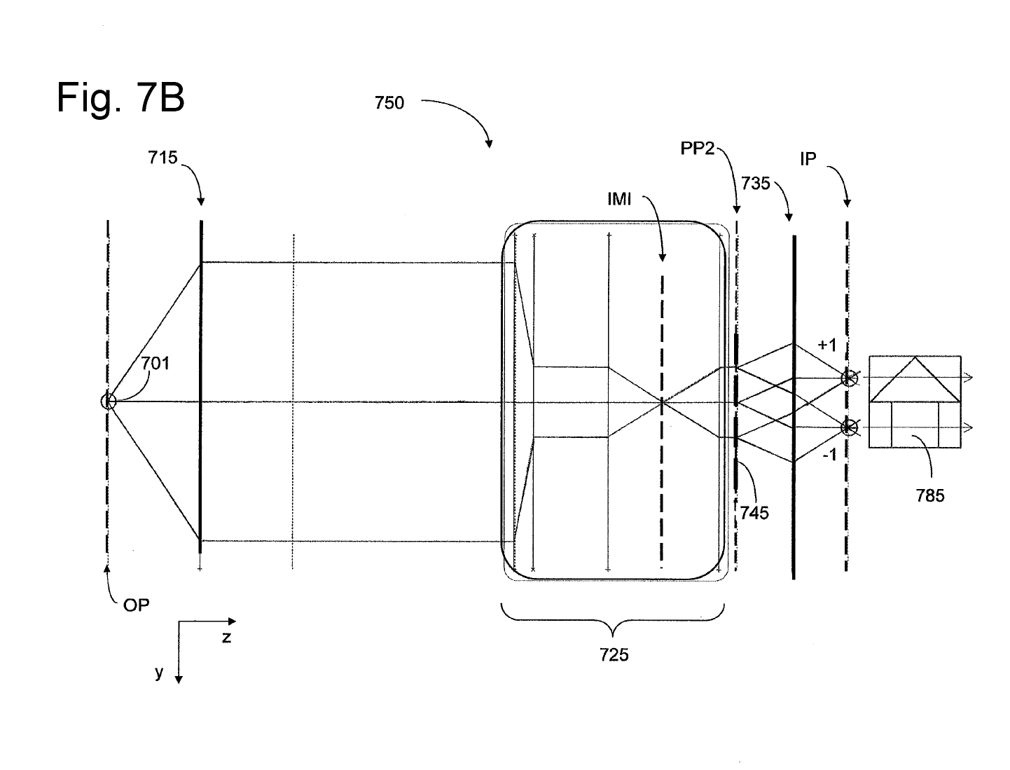

The imaging system will be discussed in even greater detail with reference to FIG. 7-9. As far as, firstly, the abovementioned target line configuration is concerned, the latter comprises a set of target lines {(hₖ, θₖ), k=1, . . . , K} which are parameterized by their spacing hₖ, and their orientation angle 74 ₖ, as is illustrated by way of example in FIG. 4A and FIG. 4B for four target lines in each case.

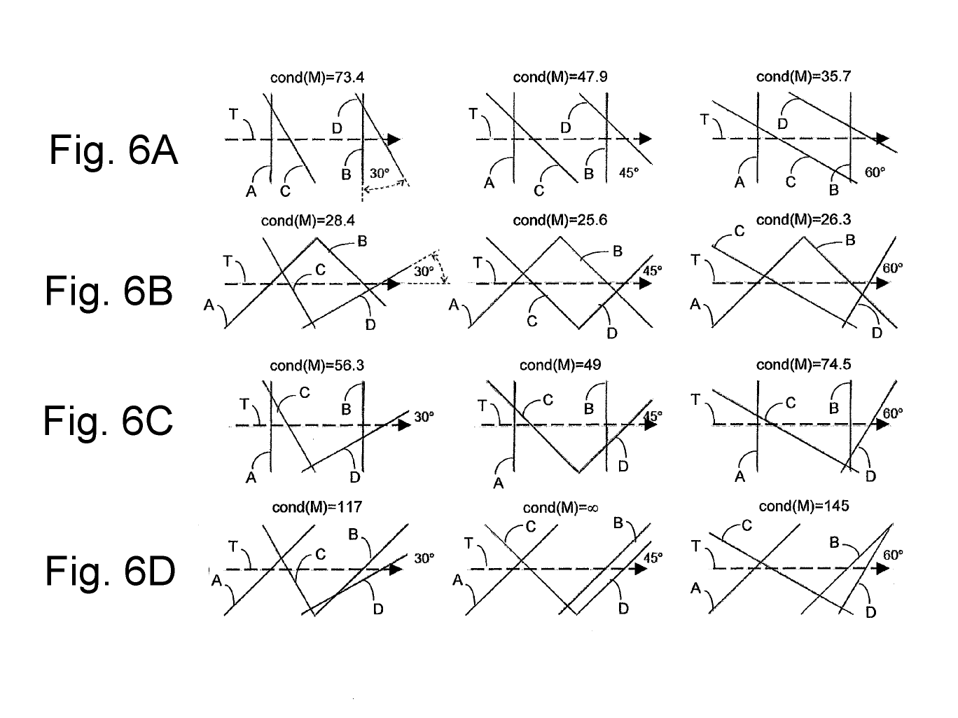

FIG. 4A shows the construction of photodetector arrangements 411, 412, . . . having a linear arrangement of the photodetector cells, for which only a simple (i.e. non-replicating) optical imaging of the flying object onto the photodetector arrangement is required. By contrast, FIG. 4B shows the construction of photodetector arrangements 421, 422, . . . having a folded arrangement of the photodetector cells, for which an optically replicating imaging is required. The folded arrangements in FIG. 4B are advantageous in particular in so far as the required measurement section can be shortened and the image field extent of the imaging system can thus also be reduced in comparison with linear arrangements in FIG. 4A. As is illustrated merely schematically in FIGS. 5A-C, the number of imaging paths (designated by “M” in FIGS. 5A-C, where M=1 in FIG. 5A, M=2 in FIG. 5B, and M=3 in FIG. 5C) is incremented by one with each further folding.

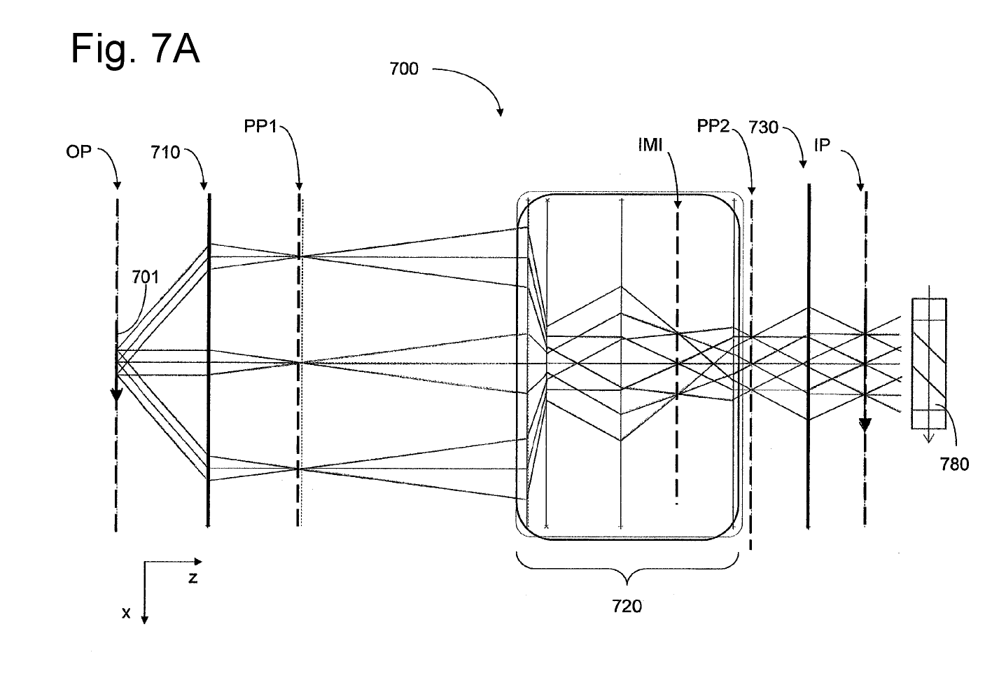

The number of photodetector cells is arbitrary in principle and can be increased e.g. in each case in order to measure higher-order flight trajectories (e.g. in the case of a parabolic flight or for a circular path measurement) and/or to improve the accuracy of the parameters through redundant measurements. Furthermore, the target line configuration, as described hereinafter below with reference to FIG. 6A-D, equation (8), can be optimized with regard to the condition number cond(M) of the design matrix M from equation (8) above.

As explained below, the target line configuration on which the optoelectronic realization according to the invention is based can be selected or optimized in a suitable manner. This further aspect of the invention is based on the consideration that both the number and the geometrical arrangement of the target lines are crucial for the “quality” of the parameter reconstruction according to equation (8). As a measure of quality for the assessment of target line configurations, use is made hereinafter of the so-called “condition number” cond(M) of the design matrix M, which describes as it were the degree of mathematical definiteness or determinability of the set of parameters for the flight trajectory. The better the determinability of the set of parameters for the flight trajectory, the smaller the value of the condition number cond(M). Without the invention being restricted thereto, hereinafter merely by way of example non-overdetermined minimal configurations with four target lines (K=4) are discussed, for which equation (8) assumes the following form.

$$( \begin{matrix}{x}_{0} \\ {y}_{0} \\ u \\ v\end{matrix} ) = inv ( {M}_{\underline{\_}} ) ( \begin{matrix}{x}_{1} \\ {x}_{2} \\ ⋮ \\ {x}_{K}\end{matrix} ) \qquad ( 9 )$$

In order to elucidate the assessment of different target line configurations, use is made of the illustrations in FIG. 6A-D, in each of which four target lines “A”, “B”, “C” and “D” are arranged in mutually different geometries and in which the flight trajectory or the trajectory (or generally the “centroid trajectory”) is likewise depicted and designated by “T”. The division of FIG. 6A-D into a first, second and third column is carried out on the basis of different orientation angles of the target line pair comprising the target lines “C” and “D”. The condition number indicated corresponds to the mean value over the angle-of-incidence interval [−20°+20°] around the centroid trajectory. In this case, “centroid trajectory” with the parameterization (x̅₀, y̅₀, ū, v̅) should be understood to mean the trajectory lying in a centred manner in the parameter intervals limited on both sides, corresponding to

$${\overline{x}}_{0} = \frac{max ( {x}_{0} ) + min ( {x}_{0} )}{2} , {\overline{y}}_{0} = \frac{max ( {y}_{0} ) + min ( {y}_{0} )}{2}$$

$$\overline{u} = \frac{max ( u ) + min ( u )}{2} , \overline{v} = \frac{max ( v ) + min ( v )}{2}$$

In detail, the target line configurations in FIG. 6A have pairwise parallel target lines comprising a pair perpendicular to the centroid trajectory, the target line configurations in FIG. 6B have pairwise perpendicular target lines comprising a pair in a 45° orientation with respect to the centroid trajectory, and the target line configurations in FIG. 6C have a pair of target lines oriented perpendicularly to the centroid trajectory and a pair of target lines perpendicular to one another. The target line configurations in FIG. 6D substantially correspond to those in FIG. 6C, wherein the target lines parallel to one another run at an angle of 45° with respect to the centroid trajectory. The following insights, in particular, can be read from FIG. 6: Not more than two target lines are permitted to run parallel to one another in the minimal configuration (the configuration having three parallel target lines in FIG. 6D, middle column, is underdetermined).

The optimal configuration corresponds to the arrangement in the middle column of FIG. 6b, which has pairwise parallel target lines in the 45 ° and −45° orientation with respect to the centroid trajectory.

The configurations in each case in the middle column of FIG. 6A and FIG. 6C having a pair of target lines perpendicular to the centroid trajectory hardly differ from one another in terms of the condition number and in this case are worse than the abovementioned optical configuration approximately by a factor of 2. One advantage of the arrangements in each case in the middle column of FIG. 6A and FIG. 6C, however, is that they optimally support the reduced problem with a known flight direction (along the x-axis).

As already mentioned, in the measuring arrangement according to the invention an imaging system is used to image the flying object situated in an object plane of the imaging system onto the photodetector arrangement situated in an image plane of the imaging system. FIG. 7A-B show merely by way of example schematic illustrations in each case of one possible imaging beam path realized within a measuring arrangement according to the invention.

The imaging system 700 in accordance with FIG. 7A has an object lens element group 710 in a Fourier configuration, a telescope 720 which is telecentric on both sides and in which an intermediate image is generated in an intermediate image plane designated by IMI, and an image lens element group 730 likewise in a Fourier configuration. The intermediate image plane IMI within the telescope 720 can be used to suppress undesired parasitic light and disturbing reflections with the aid of a stop. Three imaging beam paths that are representative of the three points x_{obj}=0, x_{obj}=+x and x_{obj}=−x on the flight trajectory are indicated. The flight trajectory—running within the object plane OP in the x-direction in the coordinate system depicted—of the flying object (e.g. of a tin droplet attaining the plasma state in an EUV laser plasma source for microlithography) is imaged onto a photodetector arrangement 780 in a magnified manner by the imaging system 700. The photodetector arrangement 780 is unfolded in the exemplary embodiment in FIG. 7A and has four target lines.

As already explained, in the case of a photodetector arrangement having a folded target line arrangement, it is necessary for the imaging beam paths passing through the imaging system to be additionally replicated in a suitable manner. FIG. 7B shows a likewise merely exemplary construction of a replicating imaging system 750, wherein components that are analogous or substantially functionally identical in comparison with FIG. 7A are designated by reference numerals increased by “5”.

The replication of the beam path in the imaging system 750 in FIG. 7B is effected with the use of the beam splitting principle using a diffractive grating and is thus suitable in particular for use in the case of sufficiently monochromatic light. The imaging system in FIG. 7B differs from that from FIG. 7A merely in that a diffractive structure 745 is inserted in the image-side pupil plane PP2. In order to realize a simple replication, use can be made, in particular, of a binary phase grating having a duty ratio of 1:1 and a phase deviation π, which concentrates e.g. in each case 41% of the light power into the first orders of diffraction and ideally completely or at least substantially eliminates the zero order.

In order to prevent the measurement result from being corrupted by a parasitic zero order of diffraction present e.g. on manufacturing defects, the photodetector arrangement 785, as indicated in FIG. 7B, is provided with a corresponding central zone between the two detection regions which cover the “used orders of diffraction” (i.e. the +1st and −1st orders of diffraction). The diffractive structure 745 or the grating for beam splitting is arranged in an accessible object- or image-side pupil plane. The orientation of the grating is chosen here preferably and as illustrated in FIG. 7B such that the splitting takes place perpendicularly to the centroid trajectory, that is to say takes place in the y-direction in the coordinate system depicted.

In further embodiments, the construction described with reference to FIG. 7B can also be extended to multiply folded multi-cell photodiodes (according to the scheme in FIG. 5). In this case, suitable design of the diffractive structure 745 or of the grating for beam splitting should ensure in each case that sufficiently identical intensities are concentrated in all used orders of diffraction.

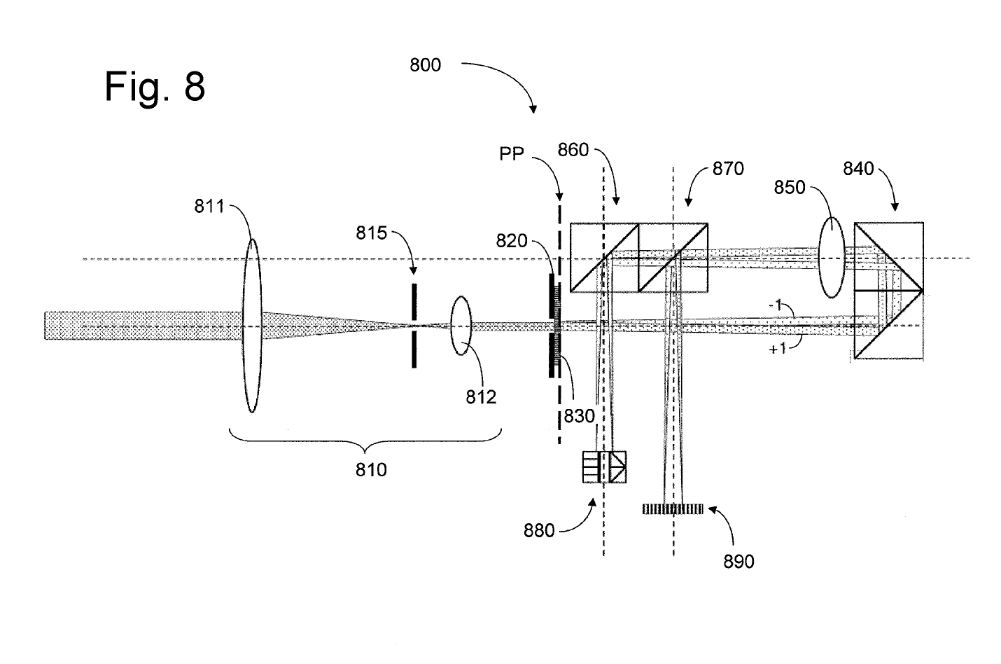

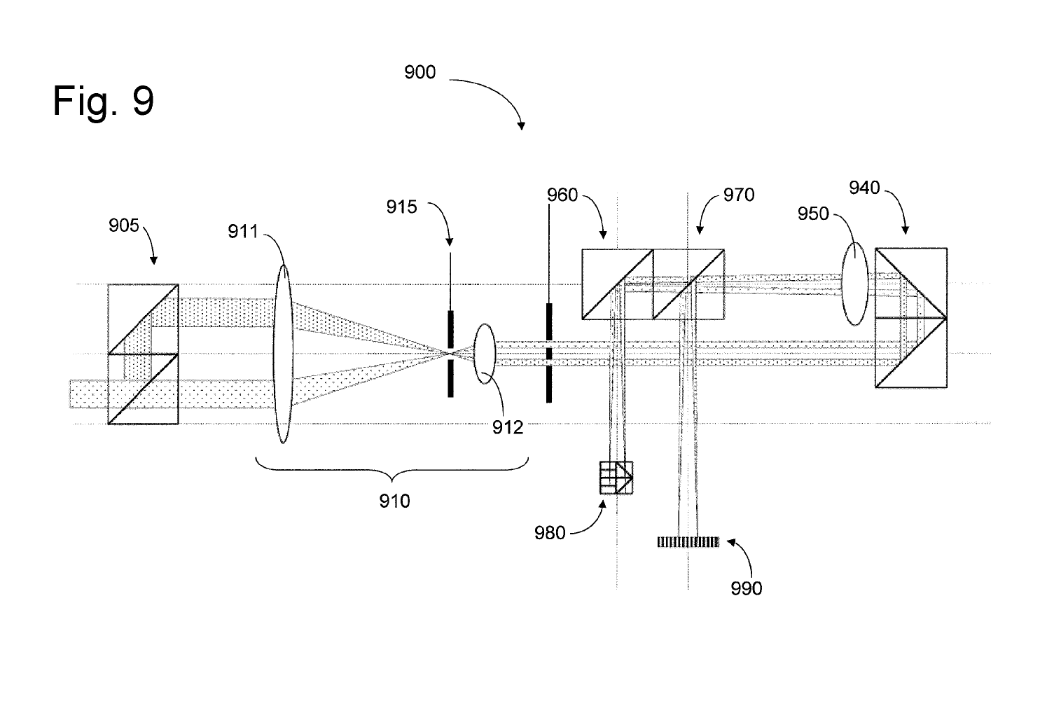

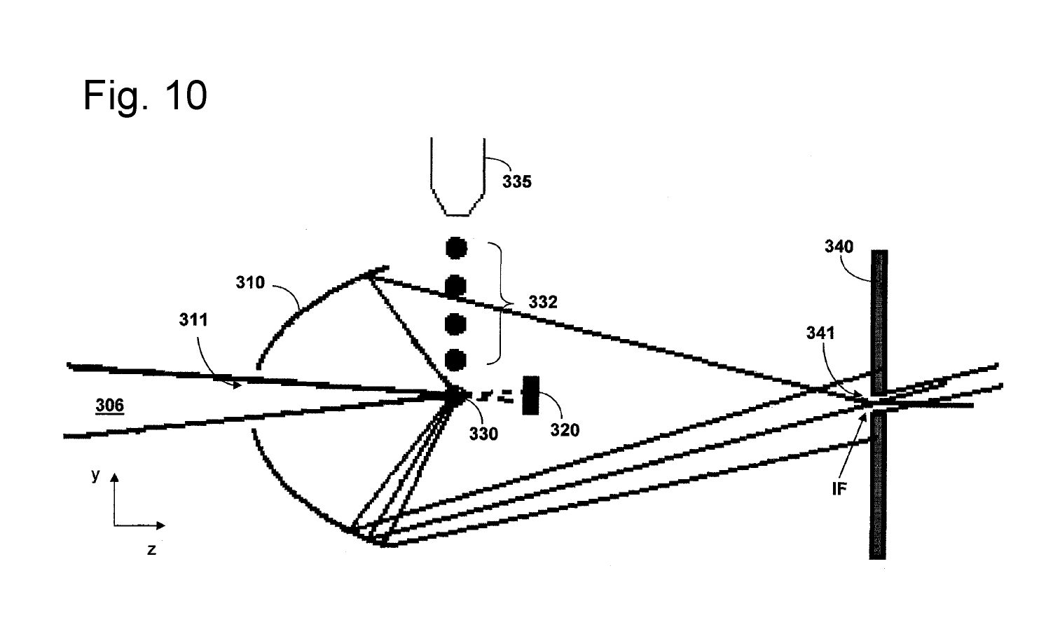

Embodiments which are suitable in each case in conjunction with a photodetector arrangement “constructed in a folded fashion” as described above will now be described below in each case with reference to FIGS. 8 and 9.

FIG. 8 shows a schematic illustration for explaining the possible construction of a measuring arrangement according to the invention in one embodiment of the invention.

In accordance with FIG. 8, a parallel beam impinges on a first lens element 811 of a telescope 810. This beam is firstly focussed by this first lens element 811 and collimated again (with a reduced beam cross section in comparison with the original beam cross section prior to impinging on the first lens element 811) by a second lens element 812 of the telescope 810. A spatial filter 815 for eliminating undesired disturbing reflections, speckle patterns, etc. is situated between the lens elements 811, 812. Situated in a pupil plane PP downstream of the telescope 810 in the light propagation direction there are firstly an aperture stop 820 (for defining or restricting the numerical aperture) and then a grating 830 for splitting the incoming beam into two partial beams corresponding to the (+1)st and the (−1)st order of diffraction, in order to realize the folding described above. Downstream of a deflection mirror 840, these two beams of the (+1)st and (−1)st orders or diffraction impinge on a Fourier lens element 850, as a result of which the two beams are directed via deflection prisms 860 and respectively 870 onto a photodetector arrangement 880 and a camera 890. The photodetector arrangement 880 has a gap for the zero order of diffraction. The image recorded by the camera 890 can be used e.g. for alignment purposes.

FIG. 9 shows a schematic illustration for explaining a further possible embodiment of a measuring arrangement according to the invention, wherein in FIG. 9 components that are analogous or substantially functionally identical in comparison with the arrangement in FIG. 8 are designated by reference numerals increased by “100”. The construction in FIG. 9 is based on the use of a beam splitter and takes account of the circumstance that the grating 830 used in the construction in FIG. 8 operates monochromatically, such that the construction in FIG. 8 is indeed suitable in the case of monochromatic light, but is less suitable for broadband light (owing to the chromatic aberration that then occurs on account of the grating 830).

In accordance with FIG. 9, a parallel beam impinging on the arrangement is firstly split into two partial beams by a beam splitter 905. The construction in FIG. 9 takes account of the circumstance that beam directing onto different sensors is prohibited owing to the high accuracy required. Rather, it is necessary to realize the imaging onto the folded photodetector arrangement 980 (in particular for instance in order to avoid scale differences) by using a single optical unit. For this purpose, in accordance with FIG. 9, beam splitting takes place actually upstream of the telescope 910. The partial beams generated as a result run off-axis and with a parallel offset through the imaging system 900 in FIG. 9. The separation of the two partial beams (which otherwise converge to a common focus in the focal plane of the Fourier optical unit) is effected by the introduction of a relative tilting of the partial beams. For this purpose, either the beam splitter group as a whole and/or one of the two beam splitters forming this group can be tilted relative to the normal arrangement (90° and) 45°.

Even though the invention has been described on the basis of specific embodiments, numerous variations and alternative embodiments are apparent to the person skilled in the art, e.g. by combination and/or exchange of features of individual embodiments. Accordingly, such variations and alternative embodiments are concomitantly encompassed by the present invention, and the scope of the invention is restricted only within the meaning of the appended patent claims and the equivalents thereof.

What is claimed is:

1. A measuring arrangement for use when determining trajectories of flying objects, comprising:
at least one photodetector arrangement comprising a plurality of photodetector cells in a monolithic construction;
wherein the photodetector arrangement is assigned exactly one imaging system, which, during operation of the measuring arrangement, images respective flying objects situated in an object plane of the imaging system onto the photodetector arrangement situated in an image plane of the imaging system; and
a time measuring device configured to measure transit instants, wherein each of the transit instants corresponds to an instant at which an image of the respective flying object, wherein the image is generated in the image plane of the imaging system, crosses a respective cell boundary between mutually adjacent photodetector cells in the photodetector arrangement.

2. The measuring arrangement according to claim 1, wherein the imaging system is configured as a replicating imaging system which generates at least two images of the object in the image plane.

3. The measuring arrangement according to claim 1, wherein the imaging system comprises at least one diffractive structure.

4. The measuring arrangement according to claim 3, wherein the diffractive structure is arranged in a pupil plane of the imaging system.

5. The measuring arrangement according to claim 1, wherein the imaging system comprises at least one optical beam splitter.

6. The measuring arrangement according to claim 1, wherein the imaging system forms at least one intermediate image.

7. The measuring arrangement according to claim 1, wherein the photodetector cells are configured as a plurality of photodiodes.

8. The measuring arrangement according to claim 1, wherein the photodetector arrangement is configured such that at least one cell boundary between mutually adjacent photodetector cells runs, during operation of the measuring arrangement, at an angle of 45°±5° with respect to a centroid trajectory of a flying object.

9. The measuring arrangement according to claim 1, wherein the photodetector arrangement is configured such that a first cell boundary between mutually adjacent photodetector cells and at least a second cell boundary between mutually adjacent photodetector cells run parallel to one another.

10. The measuring arrangement according to claim 1, integrated into a control loop for controlling the trajectories of flying objects, for controlling a radiation field acting on the objects and/or for controlling an entity acting on the objects.

11. The measuring arrangement according to claim 1, further comprising at least one camera in the imaging beam path of the imaging system.

12. The measuring arrangement according to claim 1, comprising at least two imaging systems, wherein a photodetector arrangement respectively comprising a plurality of photodetector cells in a monolithic construction, is arranged in the respective image planes of each of the imaging systems.

13. The measuring arrangement according to claim 1, configured to determine trajectories of target droplets of a laser plasma source.

14. The measuring arrangement according to claim 13, configured to determine the trajectories of target droplets of an EUV source of a microlithographic projection exposure apparatus.
